(19) United States
(12) Patent Application Publication
(10) Pub. No.: US 2024/0379844 A1
(43) Pub. Date: Nov. 14, 2024

(54) SEMICONDUCTOR DEVICE AND MANUFACTURING METHOD THEREOF

(71) Applicant: HON HAI PRECISION INDUSTRY CO., LTD., New Taipei City (TW)

(72) Inventors: Chia-Lung HUNG, New Taipei City (TW); Yi-Kai HSIAO, New Taipei City (TW); Hao-Chung KUO, New Taipei City (TW)

(21) Appl. No.: 18/652,808

(22) Filed: May 1, 2024

(30) Foreign Application Priority Data
May 8, 2023 (TW) 112117037

(51) Int. Cl. H01L 29/78; H01L 29/423; H01L 29/66

(52) U.S. Cl. CPC H01L 29/7832; H01L 29/42364; H01L 29/66893; H01L 29/7802

(57) ABSTRACT

A method of manufacturing a semiconductor device includes forming an epitaxial layer on a substrate, forming a hard mask on the epitaxial layer, in which the hard mask includes a first portion and a second portion, with a gap therebetween, performing an oxidation process to form an oxide layer on a surface of the hard mask, forming a source region in the epitaxial layer through the gap of the hard mask, forming a well region in the epitaxial layer using the second portion of the hard mask as a mask, forming a sacrificial layer on the source region and the well region, removing the second portion of the hard mask, forming a JFET region in the epitaxial layer using the sacrificial layer as a mask, forming a dielectric layer on the JFET region, removing the sacrificial layer and forming a gate structure adjacent the dielectric layer.

### CROSS-REFERENCE TO RELATED APPLICATION

This application claims priority to Taiwan Application Serial Number 112117037 filed May 8, 2023, which is herein incorporated by reference.

### BACKGROUND

### Field of Invention

Some embodiments of the present disclosure relate to a semiconductor device and a manufacturing method thereof.

### Description of Related Art

In recent years, due to environmental issues such as zero carbon emissions and electric vehicles replacing fuel vehicles, relevant research has begun to develop internationally. Power semiconductor devices made of silicon carbide have gradually replaced silicon-based power semiconductor devices, and are developing towards high-power applications with high-voltage and high-current, in which planar silicon carbide vertical double-diffused metal-oxide semiconductor-field-effect transistor (VDMOSFET) has played the main role of power transistors in related applications from 600V to 3,000V. Among them, channel resistance is still the main source of resistance contribution in the entire VDMOSFET structure. In order to reduce on-resistance (RON) of the transistor, shortening a channel length of the device and maintaining the consistent channel length is one of methods to effectively reduce RON.

### SUMMARY

Some embodiments of the present disclosure provide a method of forming a semiconductor device, which includes forming an epitaxial layer on a substrate, forming a hard mask layer on the epitaxial layer, the hard mask layer including a first portion and a second portion, with a gap between the first portion and the second portion, performing an oxidation process to form an oxide layer on a surface of the hard mask layer, forming a source region in the epitaxial layer through the gap of the hard mask layer, forming a well region in the epitaxial layer using the second portion of the hard mask layer as an ion implantation mask, forming a sacrificial dielectric layer on the source region and the well region, removing the second portion of the hard mask layer, forming a JFET region in the epitaxial layer using the sacrificial dielectric layer as an ion implantation mask, forming a dielectric layer on the JFET region, removing the sacrificial dielectric layer, and forming a gate structure at a side of the dielectric layer.

In some embodiments, the well region includes a channel region, and the channel region of the well region is adjacent to the source region, and a thickness of the oxide layer is equal to a width of the channel region of the well region.

In some embodiments, forming the gate structure at the side of the dielectric layer includes: forming a gate dielectric material layer on the source region and the well region; forming a gate material layer on the gate dielectric material layer and the dielectric layer; removing a horizontal portion of the gate material layer, leaving a vertical portion of the gate material layer to form the gate on the channel region of the well region; and patterning the gate dielectric material layer using the gate as a mask to form the gate dielectric layer.

In some embodiments, a width of the gate becomes wider as it approaches the epitaxial layer.

In some embodiments, the gate has both a vertical sidewall and an arc-shaped sidewall.

In some embodiments, when forming the sacrificial dielectric layer, the sacrificial dielectric layer is in contact with the second portion of the hard mask layer.

In some embodiments, when forming the dielectric layer, the dielectric layer is in contact with the sacrificial dielectric layer.

In some embodiments, the oxidation process has a higher oxidation rate on the surface of the hard mask layer than on the surface of the epitaxial layer.

In some embodiments, the hard mask layer is made of polycrystalline silicon.

In some embodiments, the method further includes performing an annealing process on the epitaxial layer before forming the gate structure.

Some embodiments of the present disclosure provide a semiconductor device, which includes an epitaxial layer, a junction field effect transistor region, a dielectric layer and a gate. The epitaxial layer includes a well region, a base region, a source region and a junction field effect transistor region. The well region includes a channel region. The base region is in the well region. The source region is in the well region and adjacent to the base region, in which the channel region of the well region is adjacent to the source region. The junction field effect transistor region is adjacent to the well region. The dielectric layer is on the junction field effect transistor region. The gate is adjacent to the dielectric layer and covers the channel region of the well region, and a boundary of the gate is substantially aligned with a boundary between the junction field effect transistor region and the well region.

In some embodiments, a vertical projection of the gate on the epitaxial layer does not overlap the junction field effect transistor region.

In some embodiments, a width of the gate becomes wider as it approaches the epitaxial layer.

In some embodiments, the gate has both a vertical sidewall and an arc-shaped sidewall.

In some embodiments, the vertical sidewall of the gate is in contact with the dielectric layer.

In some embodiments, the dielectric layer has a thickness between 0.8 and 1 μm.

In some embodiments, the semiconductor device further includes a gate dielectric layer between the gate and the well region, and a thickness of the gate dielectric layer is less than a thickness of the dielectric layer.

In some embodiments, the gate dielectric layer is in contact with the dielectric layer.

In some embodiments, the source region and the junction field effect transistor region are of a first semiconductor type, and the base region and the well region may be of a second semiconductor type, and the first semiconductor type is different from the second semiconductor type.

In some embodiments, the semiconductor device further includes a drift region beneath the junction field effect transistor region, and an ion doping concentration of the junction field effect transistor region is greater than that of the drift region.

Some embodiments of the present disclosure relate to a semiconductor device having a split gate structure. In some embodiments of the present disclosure, multiple doping regions and gates of the semiconductor device are formed through self-alignment processes, and thus parasitic capacitance generated on the semiconductor device due to alignment errors can be reduced, and dimensions of the doping regions and a channel region are within designed ranges.

### BRIEF DESCRIPTION OF THE DRAWINGS

FIGS. 1-15 illustrate cross-sectional views of processes for manufacturing a semiconductor device in some embodiments of the present disclosure.

### DETAILED DESCRIPTION

Some embodiments of the present disclosure relate to a semiconductor device having a split gate structure. In some embodiments of the present disclosure, multiple doping regions and gates of the semiconductor device are formed through self-alignment processes, and thus parasitic capacitance generated on the semiconductor device due to alignment errors can be reduced, and dimensions of the doping regions and a channel region are within designed ranges.

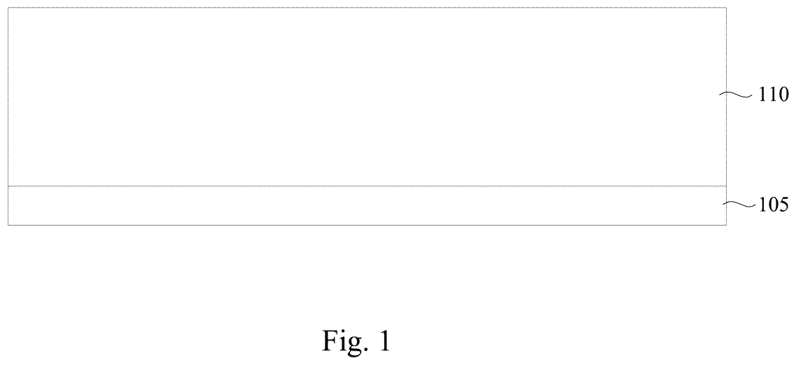

FIGS. 1-15 illustrate cross-sectional views of processes for manufacturing a semiconductor device 100 in some embodiments of the present disclosure. Referring to FIG. 1, an epitaxial layer 110 is formed on a substrate 105. The substrate 105 and the epitaxial layer 110 are any suitable substrates. In some embodiments, the substrate 105 may be made of, for example, but not limited to, silicon carbide. The substrate 105 may be doped with dopants of a first semiconductor type and is of the first semiconductor type. For example, the substrate 105 may be an N-type heavily doped substrate, such as a heavily doped region containing N-type dopants such as phosphorus, arsenic, and nitrogen. In some embodiments, the epitaxial layer 110 may be made of, for example, but not limited to, silicon carbide. The epitaxial layer 110 may be doped with dopants of the first semiconductor type and is of the first semiconductor type. For example, the epitaxial layer 110 may be an N-type lightly doped region, such as a lightly doped region containing N-type dopants such as phosphorus, arsenic, and nitrogen.

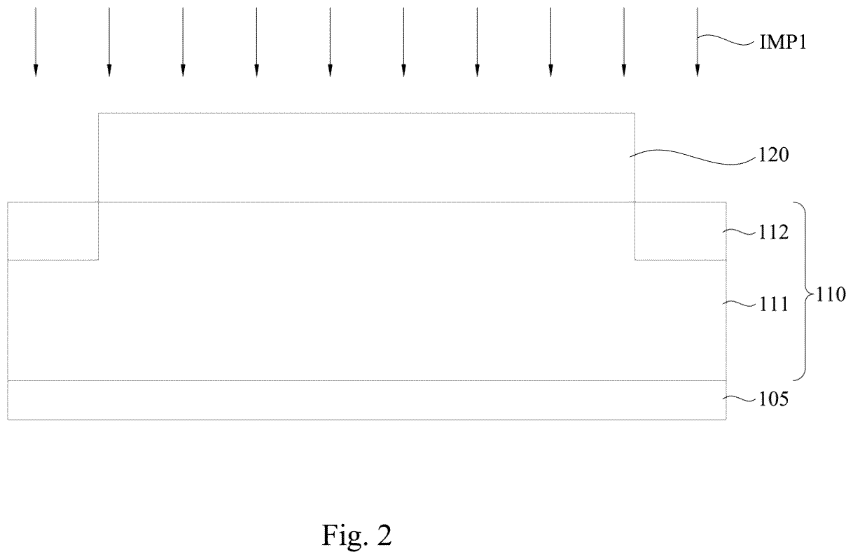

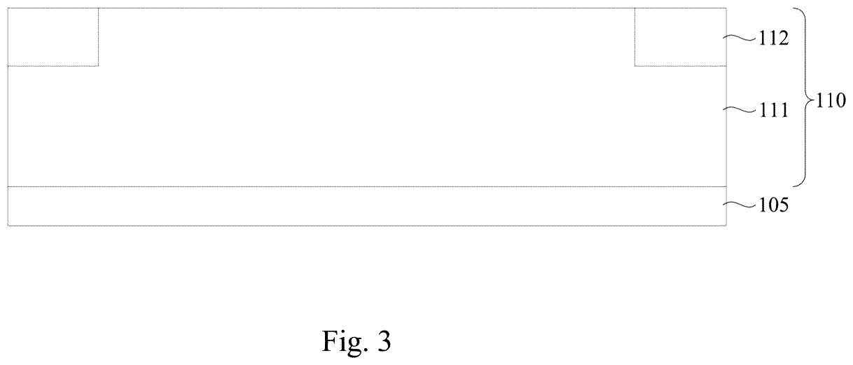

Referring to FIG. 2, a plurality of base regions 112 are formed in the epitaxial layer 110. Specifically, a hard mask layer 120 may be formed on the epitaxial layer 110 first. The hard mask layer 120 may expose a portion of the epitaxial layer 110. Next, an ion implantation process IMP1 is performed using the hard mask layer 120 as an ion implantation mask to form the base regions 112 in the epitaxial layer 110. In the ion implantation process IMP1, dopants having a second semiconductor type may be implanted into the epitaxial layer 110 to form the base regions 112 of the second semiconductor type in the epitaxial layer 110, and the second semiconductor type is different from the first semiconductor type. For example, the base region 112 may be a P-type heavily doped region, such as a heavily doped region containing P-type dopants such as boron, aluminum, and gallium. Another region of the epitaxial layer 110 that is not ion implanted by the ion implantation process IMP1 is a drift region 111. After the base regions 112 are formed, referring to FIG. 3, the hard mask layer 120 is removed. In some embodiments, the hard mask layer 120 may be removed by a suitable method, such as etching.

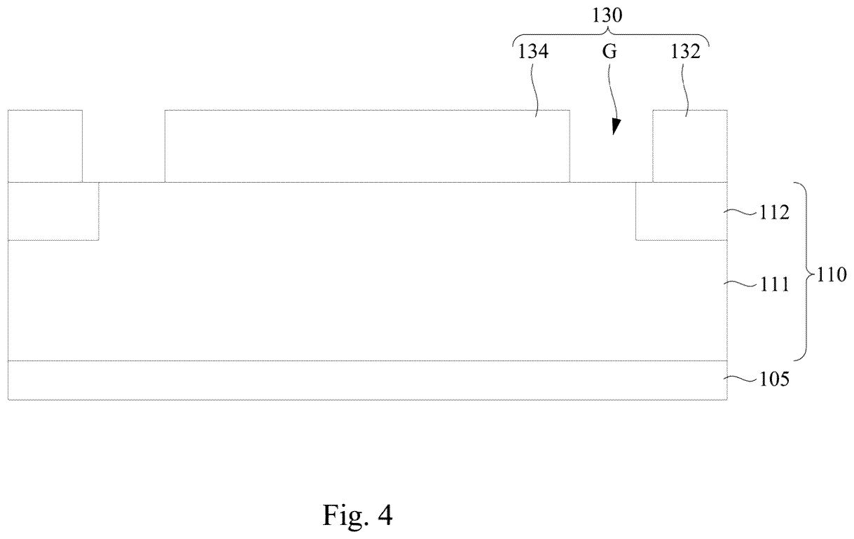

Referring to FIG. 4, a hard mask layer 130 is formed on the epitaxial layer 110. The hard mask layer 130 has a first portion 132 on the base region 112 and a second portion 134 not on the base region 112. There is a gap G between the first portion 132 and the second portion 134. The hard mask layer 130 may be defined using a conventional photolithography process. The gap G may expose a portion of the base region 112 and also expose a portion of the epitaxial layer 110 that is not occupied by the base region 112. In some embodiments, the hard mask layer 130 may be made of polycrystalline silicon.

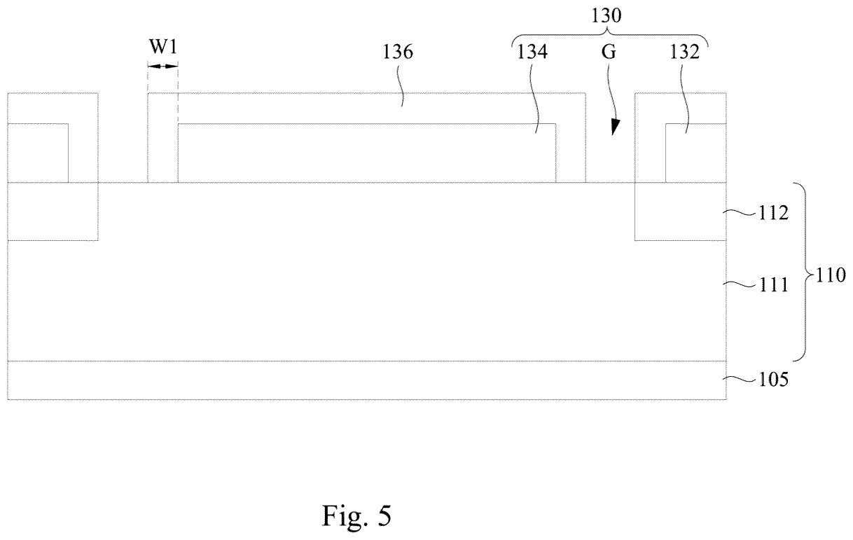

Referring to FIG. 5, an oxidation process is performed to form an oxide layer 136 on a surface of the hard mask layer 130. A portion of the oxide layer 136 may be obtained by oxidizing and sacrificing a portion of the hard mask layer 130. In some embodiments, the oxidation process is a selective oxidation process, so that the oxidation process has a higher oxidation rate on the surface of the hard mask layer 130. On the contrary, the oxidation process has a lower oxidation rate on the surface of the epitaxial layer 110, so that in some embodiments, the oxide layer 136 forms a relatively thin oxide layer on the surface of the epitaxial layer 110. In some embodiments, in order to prevent the oxidation process from also oxidizing the epitaxial layer 110, a thin protective layer may be formed on the epitaxial layer 110 to protect the epitaxial layer 110 before forming the hard mask layer 130. In some embodiments, the oxide layer 136 has a uniform thickness W1. In some embodiments, a sidewall of the oxide layer 136 may be substantially aligned with a boundary of the base region 112, as shown in FIG. 5. In some embodiments, the thickness W1 of the oxide layer 136 is between 0.5 μm and 1 μm. The thickness W1 of the oxide layer 136 may be used to determine a channel width of the semiconductor device 100.

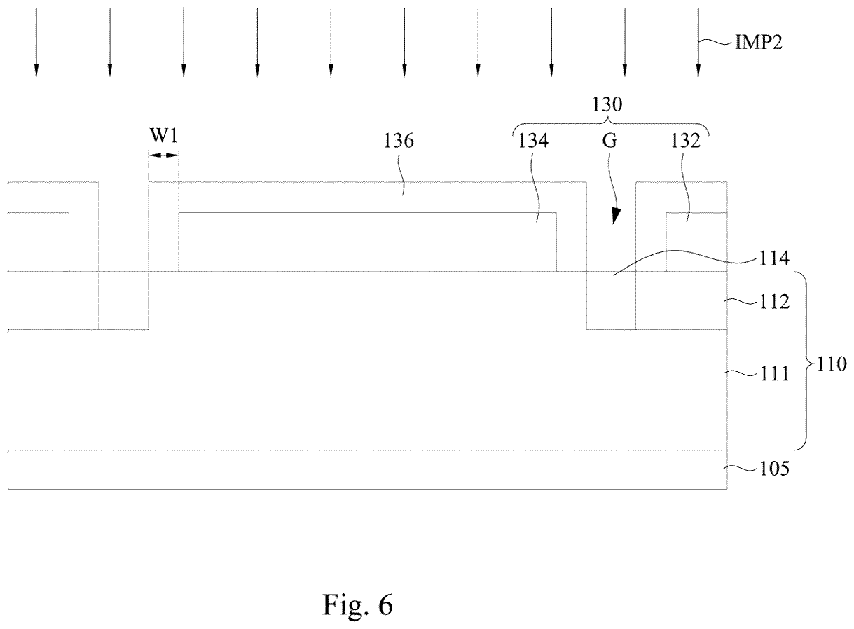

Referring to FIG. 6, a plurality of source regions 114 are formed in the epitaxial layer 110 through the gaps G of the hard mask layer 130, and each of the source regions 114 is adjacent to the base region 112. That is, the source region 114 is defined by the gap G of the hard mask layer 130. An ion implantation process IMP2 may be performed using the hard mask layer 130 and the oxide layer 136 as an ion implantation mask to form the source regions 114 in the epitaxial layer 110. In the ion implantation process IMP2, dopants having the first semiconductor type may be implanted into the epitaxial layer 110 to form the source regions 114 of the first semiconductor type in the epitaxial layer 110. For example, the source region 114 may be an N-type heavily doped region, such as a heavily doped region containing N-type dopants such as phosphorus, arsenic, and nitrogen. The gap G of the hard mask layer 130 may define both sides of the source region 114 at the same time, so that the source region 114 is adjacent to and is in contact with the base region 112.

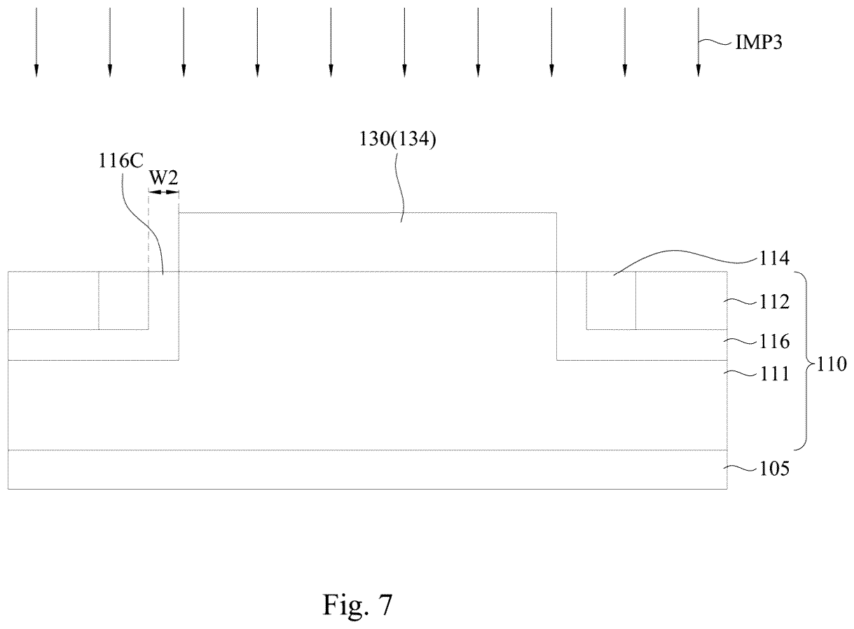

Referring to FIG. 7, the first portion 132 of the hard mask layer 130 and the oxide layer 136 are removed. Next, the second portion 134 of the hard mask layer 130 is used as an ion implantation mask to form a plurality of well regions 116 in the epitaxial layer 110. Specifically, since there is an etching selectivity ratio between the oxide layer 136 and the hard mask layer 130, the oxide layer 136 on the hard mask layer 130 may be removed first. Next, a photomask is used to remove the first portion 132 of the hard mask layer 130. As such, the base region 112 and the source region 114 are completely exposed, and a portion of the epitaxial layer 110 not occupied by the base region 112 and the source region 114 is also exposed. Next, the second portion 134 of the hard mask layer 130 may be used as an ion implantation mask to perform an ion implantation process IMP3 to form the well regions 116 in the epitaxial layer 110. In the ion implantation process IMP3, dopants having the second semiconductor type may be implanted into the epitaxial layer 110 to form the well regions 116 of the second semiconductor type in the epitaxial layer 110. For example, the well region 116 may be a P-type lightly to moderately doped region, such as a lightly to moderately doped region containing P-type dopants such as boron, aluminum, and gallium.

A bottom of the well region 116 is lower than bottoms of the base region 112 and the source region 114, so that the base region 112 and the source region 114 may be located in the well region 116. The well region 116 includes a channel region 116C adjacent to the source region 114, and the thickness W1 of the oxide layer 136 (see FIG. 6) is substantially the same as a width W2 of the channel region 116C of the well region 116. Since the oxide layer 136 has the uniform thickness W1, it is also ensured that the width W2 of the channel region 116C of the well region 116 on both sides of the second portion 134 of the hard mask layer 130 is consistent. As such, the channel region 116C of the well region 116 with the same width W2 may be defined through a self-alignment process.

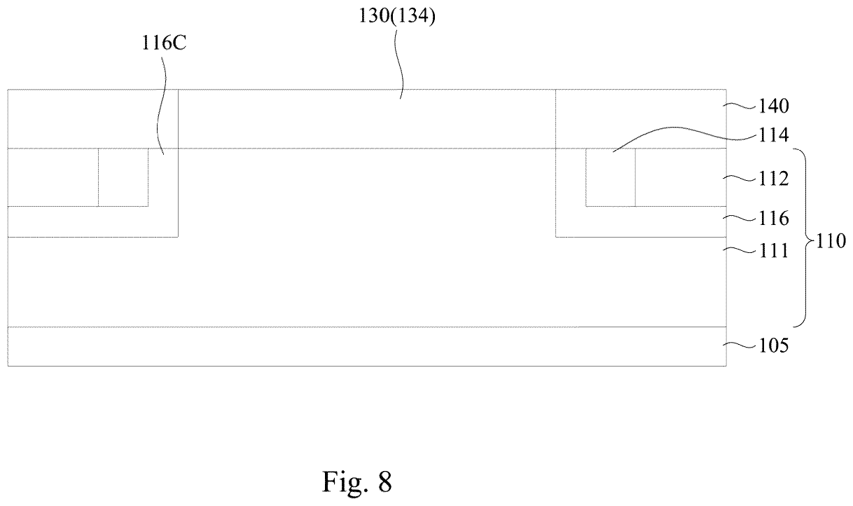

Referring to FIG. 8, a sacrificial dielectric layer 140 is formed on the base region 112, the source region 114 and the well region 116. Specifically, a sacrificial dielectric material layer may be formed on the base region 112, the source region 114, the well region 116 and the second portion 134 of the hard mask layer 130. Next, the sacrificial dielectric material layer is planarized until a surface of the second portion 134 of the hard mask layer 130 is exposed, and the sacrificial dielectric layer 140 is formed on the base region 112, the source region 114 and the well region 116. The sacrificial dielectric layer 140 is in contact with the second portion 134 of the hard mask layer 130, so that the sacrificial dielectric layer 140 may be used to define a self-aligned junction field-effect transistor (JFET) region in a subsequent process. The sacrificial dielectric layer 140 may be made of a different material than the second portion 134 of the hard mask layer 130. For example, the sacrificial dielectric layer 140 may be made of nitride.

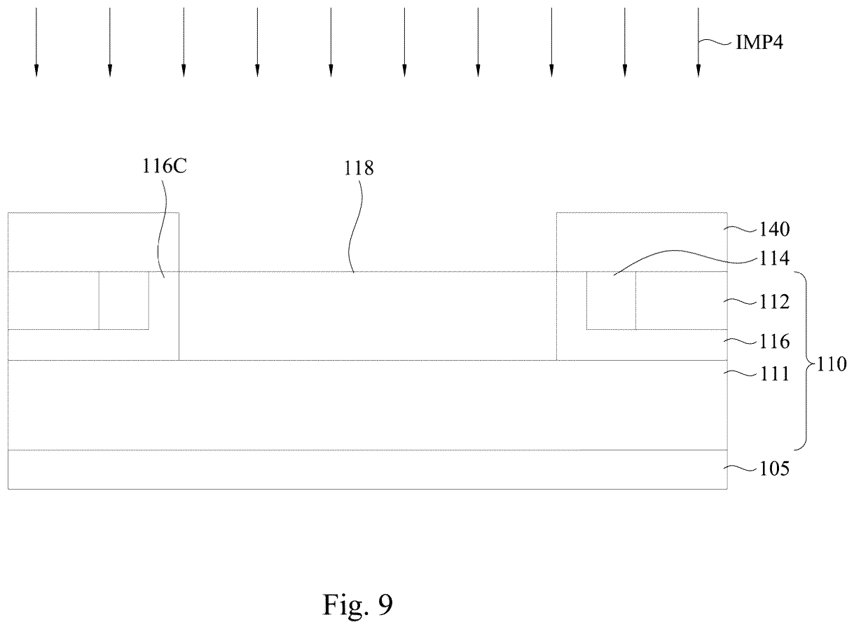

Referring to FIG. 9, the second portion 134 of the hard mask layer 130 is removed, and the sacrificial dielectric layer 140 is used as an ion implantation mask to form a junction field effect transistor (JFET) region 118 in the epitaxial layer 110. Specifically, since the second portion 134 of the hard mask layer 130 and the sacrificial dielectric layer 140 are made of different materials, the selectivity of the etching process to different materials may be used to remove the second portion 134 of the hard mask layer 130. Next, an ion implantation process IMP4 is performed using the sacrificial dielectric layer 140 as an ion implantation mask to form the JFET region 118 in the epitaxial layer 110. The JFET region 118 may be formed between two of the well regions 116. In the ion implantation process IMP4, dopants having the first semiconductor type may be implanted into the epitaxial layer 110 to form the JFET region 118 of the first semiconductor type in the epitaxial layer 110. For example, the JFET region 118 formed in the epitaxial layer 110 may be an N-type moderately or lightly doped region, such as a moderately or lightly doped region containing N-type dopants such as phosphorus, arsenic, and nitrogen. As such, the JFET region 118 may be formed in the middle of the well region 116. The location of the JFET region 118 may be defined by the gap between the sacrificial dielectric layers 140 (i.e., the location of the second portion 134 of the hard mask layer 130 in FIG. 8), so no additional photomask is required to define the position of the JFET region 118, which causes an issue of position deviation of the JFET region 118. The JFET region 118 also does not overlap with the channel region 116C of the well region 116 to reduce device characteristics. It should be noted that the formation sequence of the base region 112, the source region 114, the well region 116 and the JFET region 118 is only an example and may not be limited to what is disclosed in the present disclosure.

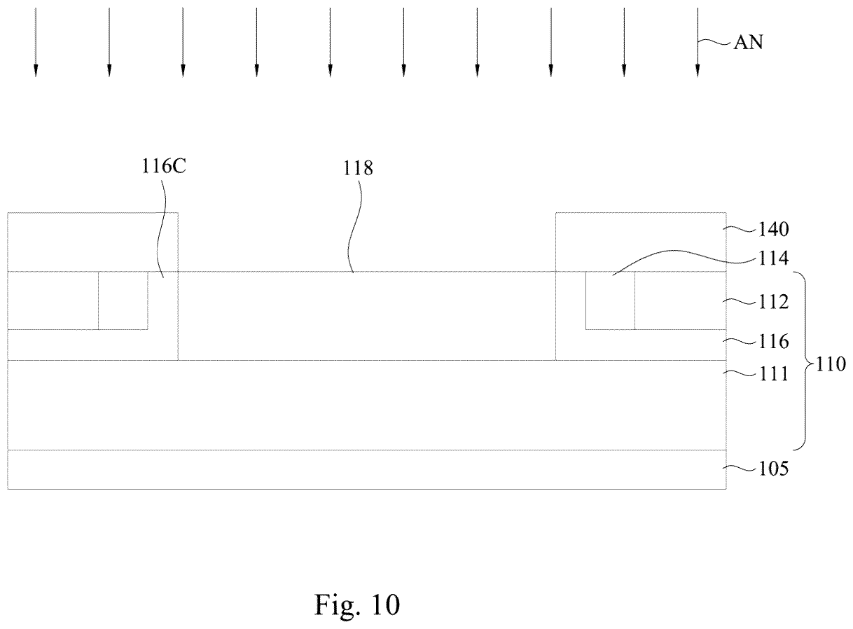

Referring to FIG. 10, an annealing process AN is performed on the epitaxial layer 110. The annealing process AN may be used to activate ions implanted in the epitaxial layer 110 and repair the damage caused by the ion implantation process. In some embodiments, an operating temperature of annealing process AN may be between 1,600 degrees Celsius and 1,700 degrees Celsius.

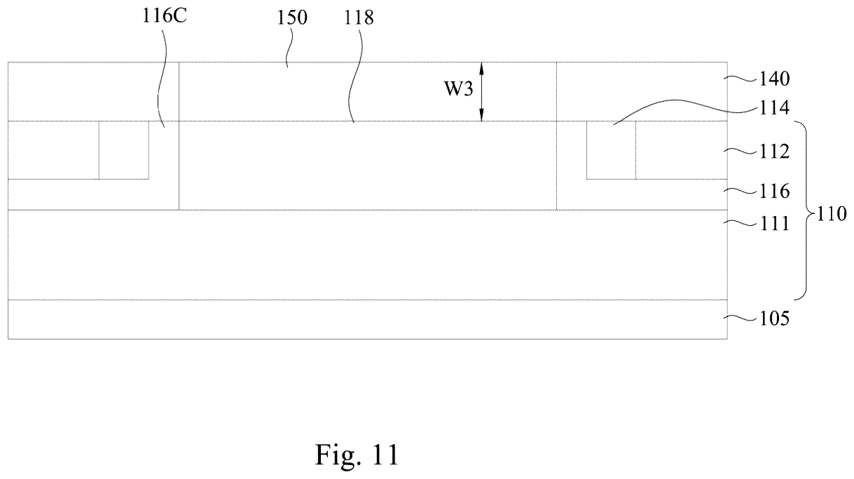

Referring to FIG. 11, a dielectric layer 150 is formed on the JFET region 118. Specifically, a dielectric material layer may be formed on the JFET region 118 and the sacrificial dielectric layer 140. Next, the dielectric material layer is planarized until a surface of the sacrificial dielectric layer 140 is exposed, and the dielectric layer 150 is formed on the JFET region 118. The dielectric layer 150 is in contact with the sacrificial dielectric layer 140, so a gate subsequently formed on both sides of the dielectric layer 150 may self-align with the channel region 116C. The dielectric layer 150 may be made of a material that has an etch selectivity ratio with the sacrificial dielectric layer 140. For example, the dielectric layer 150 may be made of oxide (SiO₂) or nitride (SiN). In some embodiments, a thickness W3 of the dielectric layer 150 may range from 0.8 to 1 μm. When a thickness of the dielectric layer 150 exceeds the disclosed range, it will cause an issue in subsequent lithography and etching processes. However, when the thickness of the dielectric layer 150 is lower than the disclosed range, there is a risk that an electric field will be too strong, resulting in reduced reliability and early breakdown. The dielectric layer 150 having the thickness W3 may be used to reduce intensity of an induced electric field, thereby reducing the risk of breakdown of the dielectric layer 150.

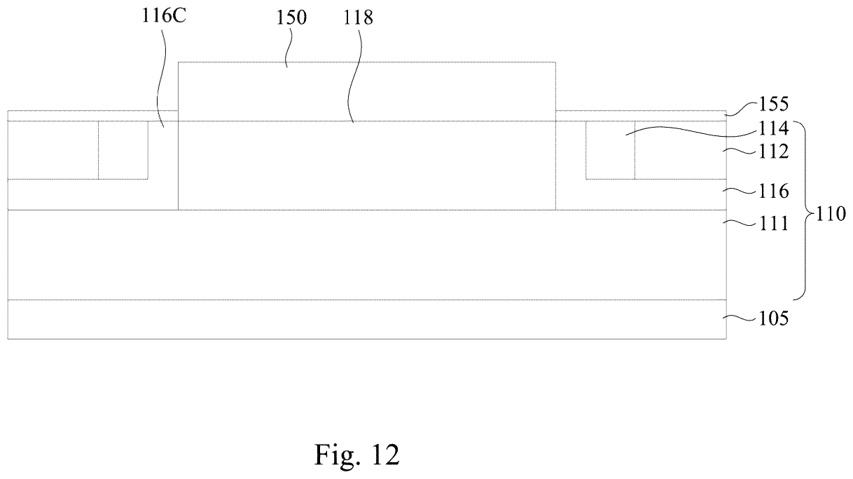

Referring to FIGS. 12 to 14, the sacrificial dielectric layer 140 is removed and a gate structure GS of the transistor is formed on both sides of the dielectric layer 150. Specifically, referring to FIG. 12, the sacrificial dielectric layer 140 is removed, and a gate dielectric material layer 155 is formed on the base region 112, the source region 114 and the well region 116. In some embodiments, a thermal oxidation process may be used to form the gate dielectric material layer 155 on the base region 112, the source region 114 and the well region 116. The gate dielectric material layer 155 may be in contact with the dielectric layer 150, and a thickness of the gate dielectric material layer 155 is less than a thickness of the dielectric layer 150. Since the dielectric layer 150 is made of a material with an etching selectivity ratio to that of the sacrificial dielectric layer 140, the sacrificial dielectric layer 140 may be removed by utilizing the selectivity of the etching process to different materials.

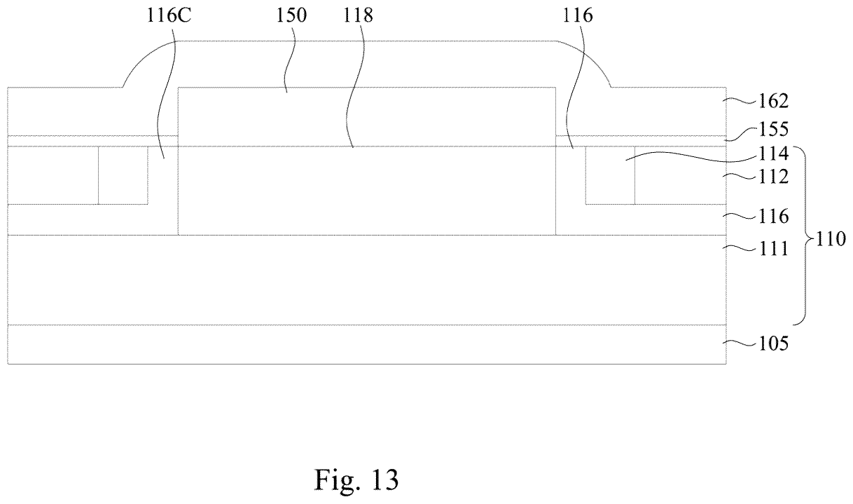

Next, referring to FIG. 13, a gate material layer 162 is formed on the gate dielectric material layer 155 and the dielectric layer 150. The process of forming the gate material layer 162 is a conformal deposition process, so the gate material layer 162 may be conformally formed on the gate dielectric material layer 155 and the dielectric layer 150. That is, the gate material layer 162 has a uniform thickness.

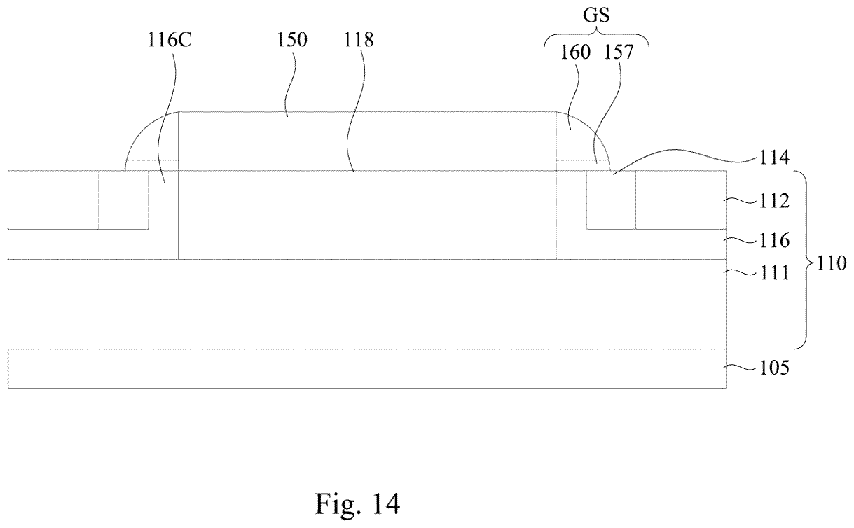

Referring to FIG. 14, a horizontal portion of the gate material layer 162 is removed, leaving the vertical portion of the gate material layer 162 to form a gate 160 on the channel region 116C of the well region 116, and the gate dielectric material layer 155 is then patterned using the gate 160 as a mask to form to the gate dielectric layer 157. The gate 160 may be formed on both sides of the dielectric layer 150, and the gate dielectric layer 157 is formed between the gate 160 and the well region 116. The gate dielectric layer 157 and the gate 160 may be collectively referred to as the gate structure GS. A dry etching process may be used to remove the horizontal portion of the gate material layer 162. Since the gate material layer 162 has the uniform thickness, a width of the gate 160 may also be ensured to be consistent. The width of the gate 160 may be adjusted by adjusting a thickness of the gate material layer 162, so that the gate 160 may completely cover the channel region 116C of the well region 116 to avoid an increase in resistance. In addition, the gate 160 may self-align with the boundary between the channel region 116C of the well region 116 and the JFET region 118, and prevent the gate 160 from contacting or crossing the JFET region 118 to generate parasitic capacitance, so as to prevent this parasitic capacitance from affecting high-frequency conversion characteristics and increasing power consumption. This may also reduce the channel resistance effect of the semiconductor device 100. In some embodiments, the gate 160 may be made of a low-resistance material such as polysilicon or metal. Since the gate 160 is formed after the annealing process AN in FIG. 10, a high temperature of the annealing process AN will not have a negative impact on the gate 160. For example, the high temperature of the annealing process AN will not melt the gate 160. Since the gate 160 is formed by etching the gate material layer 162 conformally covering dielectric layer 150, the gate 160 has a structure that is narrow at the top and wide at the bottom. That is, the width of the gate 160 becomes wider as it approaches the epitaxial layer 110. In addition, the gate 160 has both a vertical sidewall and an arc-shaped sidewall, and the vertical sidewall of the gate 160 is in contact with the dielectric layer 150.

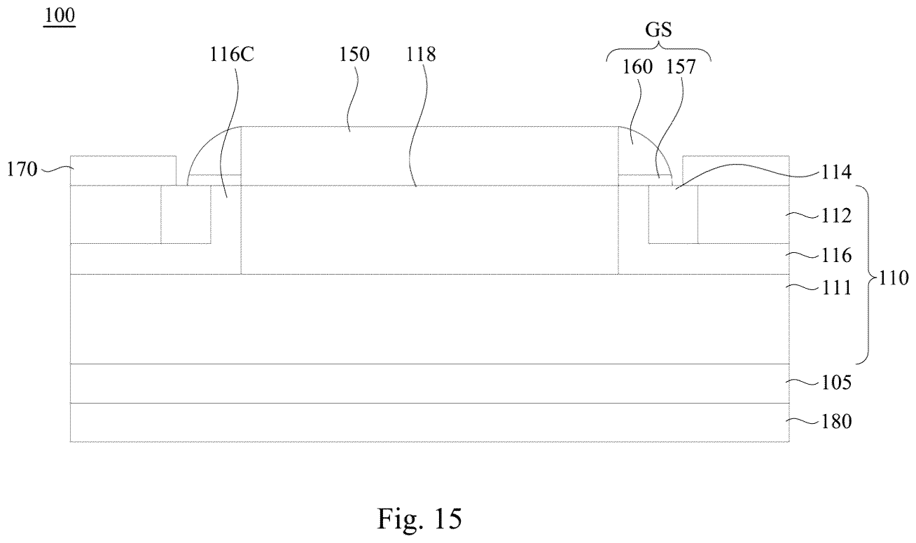

Referring to FIG. 15, a source contact 170 is formed on the base region 112 and the source region 114, and a drain electrode 180 is formed beneath the substrate 105. At this point, the semiconductor device 100 is formed. The semiconductor device 100 may include a substrate 105, an epitaxial layer 110, a dielectric layer 150 and a gate 160. The epitaxial layer 110 is on the substrate 105. The epitaxial layer 110 includes a drift region 111, a well region 116, a base region 112, a source region 114 and a JFET region 118. The well region 116 includes a channel region 116C. The base region 112 is in the well region 116. The source region 114 is in the well region 116 and is adjacent to the base region 112, in which the channel region 116C of the well region 116 is adjacent to the source region 114. The JFET region 118 is adjacent to the well region 116. That is, the channel region 116C of the well region 116 is located between the JFET region 118 and the source region 114, and the JFET region 118 is between two different of the well regions 116. The drift region 111 is beneath the well region 116 and the JFET region 118. The substrate 105, the drift region 111, the source region 114 and the JFET region 118 may be of the first semiconductor type, and the base region 112 and the well region 116 may be of the second semiconductor type, and the first semiconductor type is different from the second semiconductor type. An ion doping concentration of the source region 114 is greater than that of the JFET region 118, and an ion doping concentration of the JFET region 118 is greater than that of the drift region 111. The ion doping concentration of the base region 112 is greater than that of the well region 116. In some embodiments, the ion doping concentration of the source region 114 is 1.0E19/cm³ to 5.0E20/cm³, and the ion doping concentration of the JFET region 118 and the drift region 111 is 1.0E15/cm³ to 5.0E17/cm³. The ion doping concentration of the base region 112 is 1.0E19/cm³ to 5.0E20/cm³, and the ion doping concentration of the well region 116 is 1.0E16/cm³ to 1.0E18/cm³.

The dielectric layer 150 is on the JFET region 118. The dielectric layer 150 may be used to reduce the intensity of the electric field induced here, thereby reducing the risk of breakdown of the dielectric layer 150. The gate 160 is adjacent to the dielectric layer 150 and covers the channel region 116C of the well region 116, and the boundary of the gate 160 is substantially aligned with the boundary between the JFET region 118 and the well region 116. The gate 160 is in direct contact with the channel region 116C. The gate 160 is a split gate, that is, the gate 160 is formed on both sides of the dielectric layer 150 instead of on the dielectric layer 150. The split gate may reduce high-voltage stress damage to the dielectric layer 150 and improve reliability performance. In addition, the vertical projection of the gate 160 on the epitaxial layer 110 does not overlap with the JFET region 118. Therefore, the gate 160 may reduce the parasitic capacitance and increase the switching rate, thereby reducing the power loss caused during switching. In addition, the thickness W3 (FIG. 11) of the dielectric layer 150 between the gate 160 may be very thick to reduce the intensity of the electric field induced by the dielectric layer 150 and thereby reduce the risk of breakdown of the dielectric layer 150. The semiconductor device 100 further includes a gate dielectric layer 157 between the gate 160 and the well region 116. The thickness of the gate dielectric layer 157 is less than the thickness of the dielectric layer 150, and the gate dielectric layer 157 is in contact with the dielectric layer 150. The semiconductor device 100 further includes a source contact 170 on the base region 112 and the source region 114 and a drain electrode 180 beneath the epitaxial layer 110.

In summary, the channel region, the source region, the JFET region and the gate of the semiconductor device according to some embodiments of the present disclosure may be formed through self-alignment, so a single mask (i.e., the photomask used to define the hard mask layer in FIG. 4) may be used to complete the ion implantation processes of the channel region, the source region, the JFET region and the gate formation. As such, the issue of position deviation or size inconsistency in the channel region, the source region, the JFET region and the gate caused by the alignment error of the photomask can be avoided. In addition, parasitic capacitance in the semiconductor device can be reduced, and the semiconductor device can have lower impedance.

The above are only some embodiments of the present disclosure, not all embodiments. Any equivalent changes made to the technical solution of the present disclosure by those of ordinary skill in the art after reading the description of the present disclosure shall be covered by the claims of the present disclosure.

What is claimed is:

1. A method of manufacturing a semiconductor device, comprising:
forming an epitaxial layer on a substrate;
forming a hard mask layer on the epitaxial layer, the hard mask layer having a first portion and a second portion, with a gap between the first portion and the second portion;
performing an oxidation process to form an oxide layer on a surface of the hard mask layer;
forming a source region in the epitaxial layer through the gap of the hard mask layer;
removing the first portion of the hard mask layer and the oxide layer;
forming a well region in the epitaxial layer using the second portion of the hard mask layer as an ion implantation mask;
forming a sacrificial dielectric layer on the source region and the well region;
removing the second portion of the hard mask layer;
forming a junction field effect transistor region in the epitaxial layer using the sacrificial dielectric layer as an ion implantation mask;
forming a dielectric layer on the junction field effect transistor region;
removing the sacrificial dielectric layer; and
forming a gate structure at a side of the dielectric layer.

2. The method of claim 1, wherein the well region comprises a channel region, and the channel region of the well region is adjacent to the source region, and a thickness of the oxide layer is equal to a width of the channel region of the well region.

3. The method of claim 2, wherein forming the gate structure at the side of the dielectric layer comprises:
forming a gate dielectric material layer on the source region and the well region;
forming a gate material layer on the gate dielectric material layer and the dielectric layer;
removing a horizontal portion of the gate material layer, leaving a vertical portion of the gate material layer to form a gate on the channel region of the well region; and
patterning the gate dielectric material layer using the gate as a mask to form a gate dielectric layer.

4. The method of claim 3, wherein a width of the gate becomes wider as it approaches the epitaxial layer.

5. The method of claim 3, wherein the gate has both a vertical sidewall and an arc-shaped sidewall.

6. The method of claim 1, wherein when forming the sacrificial dielectric layer, the sacrificial dielectric layer is in contact with the second portion of the hard mask layer.

7. The method of claim 1, wherein when forming the dielectric layer, the dielectric layer is in contact with the sacrificial dielectric layer.

8. The method of claim 1, wherein the oxidation process has a higher oxidation rate on the surface of the hard mask layer than on the surface of the epitaxial layer.

9. The method of claim 1, wherein the hard mask layer is made of polycrystalline silicon.

10. The method of claim 1, further comprising:
performing an annealing process on the epitaxial layer before forming the gate structure.

11. A semiconductor device, comprising:
an epitaxial layer, the epitaxial layer comprising:
a well region, the well region comprising a channel region;
a base region, in the well region;
a source region, in the well region and adjacent to the base region, wherein the channel region of the well region is adjacent to the source region; and
a junction field effect transistor region adjacent to the well region;
a dielectric layer, on the junction field effect transistor region; and
a gate, adjacent to the dielectric layer and covering the channel region of the well region, and a boundary of the gate being substantially aligned with a boundary between the junction field effect transistor region and the well region.

12. The semiconductor device of claim 11, wherein a width of the gate becomes wider as it approaches the epitaxial layer.

13. The semiconductor device of claim 11, wherein the gate has both a vertical sidewall and an arc-shaped sidewall.

14. The semiconductor device of claim 13, wherein the vertical sidewall of the gate is in contact with the dielectric layer.

15. The semiconductor device of claim 11, wherein a vertical projection of the gate on the epitaxial layer does not overlap the junction field effect transistor region.

16. The semiconductor device of claim 11, wherein the dielectric layer has a thickness between 0.8 and 1 μm.

17. The semiconductor device of claim 11, further comprising a gate dielectric layer between the gate and the well region, and a thickness of the gate dielectric layer is less than a thickness of the dielectric layer.

18. The semiconductor device of claim 17, wherein the gate dielectric layer is in contact with the dielectric layer.

19. The semiconductor device of claim 11, wherein the source region and the junction field effect transistor region are of a first semiconductor type, and the base region and the well region may be of a second semiconductor type, and the first semiconductor type is different from the second semiconductor type.

20. The semiconductor device of claim 11, further comprising a drift region beneath the junction field effect transistor region, and an ion doping concentration of the junction field effect transistor region is greater than that of the drift region.
